(19) United States
(12) Patent Application Publication
(10) Pub. No.: US 2026/0298977 A1
(43) Pub. Date: Oct. 1, 2026

(54) PROBE HEAD WITH CONTACT PROBES HAVING AN IMPROVED CONFIGURATION

(71) Applicant: TECHNOPROBE S.P.A., Cernusco Lombardone (LC) (IT)

(72) Inventors: Raffaele VALLAURI, Cernusco Lombardone (LC) (IT); Nadia PADERNO, Cernusco Lombardone (LC) (IT); Camilla CAMARRI, Cernusco Lombardone (LC) (IT); Giulia STUCCHI, Cernusco Lombardone (LC) (IT); Stefano FELICI, Cernusco Lombardone (LC) (IT); Fabio MORGANA, Cernusco Lombardone (LC) (IT); Roberto CRIPPA, Cernusco Lombardone (LC) (IT); Giuseppe CRIPPA, Cernusco Lombardone (LC) (IT)

(73) Assignee: TECHNOPROBE S.P.A., Cernusco Lombardone (LC) (IT)

(21) Appl. No.: 19/477,185

(22) PCT Filed: Apr. 11, 2024
(86) PCT No.: PCT/EP2024/059817

§ 371 Date: Oct. 21, 2025

(30) Foreign Application Priority Data
Apr. 26, 2023 (IT) 102023000008088
Apr. 26, 2023 (IT) 102023000008100

(51) Int. Cl. G01R 1/067; G01R 1/073

(52) U.S. Cl. CPC G01R 1/06716; G01R 1/07307

(57) ABSTRACT

A probe head for the testing of electronic devices is disclosed having a contact probe that includes a body which extends between first and second ends adapted to contact respective contact pads, and a guide having a guide hole configured for housing at least a portion of the contact probe. The contact probe includes an intermediate section arranged between the first and second ends which is elastically compliant, wherein the elastically compliant intermediate section is structured as a plurality of elastic elements which follow one another in series so that the elastically compliant intermediate section is not rectilinear. At least one of the elastic elements is in contact with a wall of the guide hole.

### FIELD OF APPLICATION

The present invention relates to a probe head adapted to perform the testing of electronic devices integrated on a semiconductor wafer, for instance high-frequency devices. The following description is made with reference to this field of application with the only purpose of simplifying the exposition thereof.

### PRIOR ART

As it is well known, a probe head is essentially a device adapted to electrically contact a plurality of contact pads of a microstructure, particularly an electronic device integrated on a semiconductor wafer, with corresponding channels of a testing apparatus which performs the functionality testing thereof.

The testing performed on integrated circuits is in particular useful for detecting and isolating defective circuits as early as in the production phase. Normally, the probe heads are thus used for the testing of the circuits integrated on wafers before cutting and assembling them inside a chip containment package.

A probe head essentially comprises a plurality of contact probes housed in a pair of supports or guides which are substantially plate-like and parallel to each other. These plate-like supports are equipped with proper guide holes and are located at a certain distance from each other, so as to leave a free area or air gap for the movement and the possible deformation of the contact probes, which are normally formed by wires of special alloys with good electrical and mechanical properties.

The contact probes generally extend between a first end portion, intended to contact the pads of the device under test, and a second end portion, intended to contact a space transformer or a printed circuit board (PCB).

The correct operation of a probe head is basically linked to two parameters: the vertical movement (or overtravel) of the contact probes and the horizontal movement (or scrub) of the contact tips of these probes on the pads during the contact with the device under test. All these features are to be evaluated and calibrated in the manufacturing step of a probe head, the good electrical connection between the contact probes and the device under test should always be ensured. It is thus particularly important to ensure a proper contact of the contact probes with the various pads during the test.

In general, the maximum overtravel of a contact probe is equal to the dimensions of the probe part projecting with respect to the lower guide, this projecting part returning into the lower guide in case of contact with the device under test due to the bending and deformation of the probe itself. The height of this projecting part is however constrained by the mechanical resistance of the probe and is normally reduced. Moreover, it should be added that the maximum value of the overtravel of the probes can be only theoretically reached, since even with much smaller overtravels problems linked to the interlocking and to the deformation of the probes occur.

In accordance with some known solutions, contact probes having a pre-deformation are manufactured, but these solutions however have various drawbacks, such as for instance the difficult maintenance and the need for particular expedients for the retention of the probes, as well as interlocking problems during the test. Another problem of these known solutions is linked to the wear of the contact pads caused by the probes themselves.

Furthermore, very short probes have been manufactured in the past to ensure optimum performances also for high-frequency tests, where the length of the probe is a significant problem, in particular due to the self-inductance phenomenon. In this case, however, the reduced length of the body of the probes dramatically increases the rigidity of the probe itself, causing an increase in the force exerted by the respective contact tip on the various pads, which can lead to a breaking of these pads, with irreparable damage of the device under test. The increase in the rigidity of the contact probe due to the reduction in the length of the body thereof also increases the risk of breaking the probes themselves. In this case too, there is thus the need for contact probes which can ensure an improved contact during the test.

The technical problem of the present invention is to devise a probe head having such structural and functional features as to allow the limitations and drawbacks still affecting the known solutions to be overcome, said probe head being in particular ale to ensure an optimum contact with the contact pads during the test, for instance with an improved control of the contact force of the probes, while ensuring a proper retention of the probe and a contact thereof with the walls of the guide holes.

### SUMMARY OF THE INVENTION

The solution idea underlying the present invention is to manufacture a probe head in which the contact probes are subjected, during the test, to an elastic deformation preferably occurring mainly (but not necessarily) in the longitudinal direction. In particular, the contact probes have at least one elastically compliant (or yielding) intermediate section along a substantially longitudinal direction, so that they substantially act as an elastic spring, wherein the above-mentioned elastically compliant intermediate section is not rectilinear, so that at least one portion thereof contacts a corresponding wall of the guide holes which house the contact probes.

Based on this solution idea, the above technical problem is solved by a probe head for the testing of electronic devices, comprising at least one contact probe comprising a body which extends between a first end and a second end, said ends being adapted to contact respective contact pads, at least one guide comprising at least one guide hole configured to house at least one portion of the contact probe, wherein the contact probe comprises at least one intermediate section arranged between the first end and the second end which is elastically compliant (or yielding), and wherein the elastically compliant intermediate section is structured in (comprises) a plurality of elastic elements (or elastic half-sections or elastic sections) which follow one another, so that said elastically compliant intermediate section is not rectilinear in section, wherein at least one of said elastic elements is in contact with a wall of the guide hole.

More particularly, the invention comprises the following additional and optional features, taken individually or in case in combination.

According to an aspect of the present invention, at least two of the elastic elements may be offset to each other with respect to a reference axis that is orthogonal to the guide, namely a vertical axis (for instance the longitudinal axis of the contact probe).

According to an aspect of the present invention, the elastic elements may extend along respective axes, which are shifted with respect to each other, so that said elastic elements are offset (shifted) to each other.

According to an aspect of the present invention, one or more of the edges (namely the intersection of sides of said elastic elements or half-sections) at least of the elastic elements that are in contact with the walls of the guide hole may be beveled.

According to an aspect of the present invention, the probe head may further comprise a conductive portion formed on the guide, said conductive portion including at least one group of said guide holes and being adapted to contact and short-circuit a corresponding group of contact probes that are housed in said group of holes and are intended to carry a given kind of signal, thereby forming a given conductive domain, wherein at least one portion of the contact probe is in contact with said conductive portion.

According to an aspect of the present invention, at least one portion of at least one wall of the guide hole may be covered by the conductive portion, wherein the contact of the probe also occurs with said metalized wall.

According to an aspect of the present invention, at least one of the elastic elements may be configured to contact the conductive portion.

It is also possible an embodiment in which only the wall of the probes (or at least a portion thereof) are covered by a metal layer and the elastically compliant intermediate section is in contact with said wall having the metal layer.

According to an aspect of the present invention, the contact probe may have a length lower than 2000 μm, preferably lower than 1000 μm, even more preferably equal to or lower than 800 μm, said length being measured along the longitudinal axis of the contact probe.

According to an aspect of the present invention, the elastically compliant intermediate section may be positioned at the guide, so as to be at least partially housed in the guide hole.

According to an aspect of the present invention, the first end of the contact probe may comprise a high hardness material, such as rhodium.

According to an aspect of the present invention, at least one of the elastic elements may comprise a projecting element which protrudes toward an adjacent elastic element and is configured to contact a portion of said adjacent elastic element during the testing of the electronic device, said portion being separated from said projecting element in the rest conditions.

The features and advantages of the probe head according to the invention will be apparent from the following description of an exemplary embodiment thereof given by way of non-limiting example with reference to the attached drawings.

### BRIEF DESCRIPTION OF THE DRAWINGS

In the drawings:

FIG. 1 schematically shows a probe head in which a contact probe comprises an elastically compliant intermediate section;

FIG. 2 schematically shows a probe head according to an embodiment of the present invention which envisages two overlapped guide portions;

FIG. 3 schematically shows a probe head according to an embodiment of the present invention which provides for the presence of a lower guide and of an upper guide;

FIG. 4 schematically shows a probe head according to an embodiment of the present invention which envisages the presence of conductive portions to short-circuit groups of probes;

FIGS. 5 to 7 schematically show embodiments of the present invention in which conductive portions are arranged in various ways at a guide of the probe head;

FIGS. 8A-8B schematically show a probe head according to the present invention in which a non-rectilinear elastically compliant intermediate section is present;

FIG. 9 schematically shows a probe head according to a further embodiment of the present invention; and

FIG. 10 schematically shows a probe head according to a further embodiment of the present invention.

### DETAILED DESCRIPTION

With the reference to the figures, a probe head for the testing of electronic devices manufactured according to the present invention is globally and schematically indicated with reference number 100.

It should be noted that the figures represent schematic views and are not drawn to scale, but they are instead drawn so as to emphasize the important features of the invention. Furthermore, in the figures, the different elements are schematically represented, and the shape thereof may vary depending on the desired application. Moreover, it should be noted that, in the figures, identical reference numbers refer to elements which are identical in shape or function. Finally, particular expedients described in relation to an embodiment illustrated in a figure can also be used for the other embodiments illustrated in the other figures.

Moreover, it is noted that, unless expressly stated, described process steps can also be reversed if necessary.

The probe head 100 is adapted to connect (directly or more preferably indirectly by means of a space transformer and/or a PCB) with an equipment (not illustrated in the figures) to perform the testing of electronic devices integrated on a semiconductor wafer 20, for instance (but not necessarily) high-frequency devices.

It is noted that, in the context of the present invention, the term “probe head” is used to indicate a test device without being limited by the presence or absence of particular components, in addition to what is defined by the attached claims. In general, this term thus indicates a set of components which can be associated with further components for checking devices integrated on the above semiconductor wafer 20, and thus it generally indicates a system for measuring electronic devices.

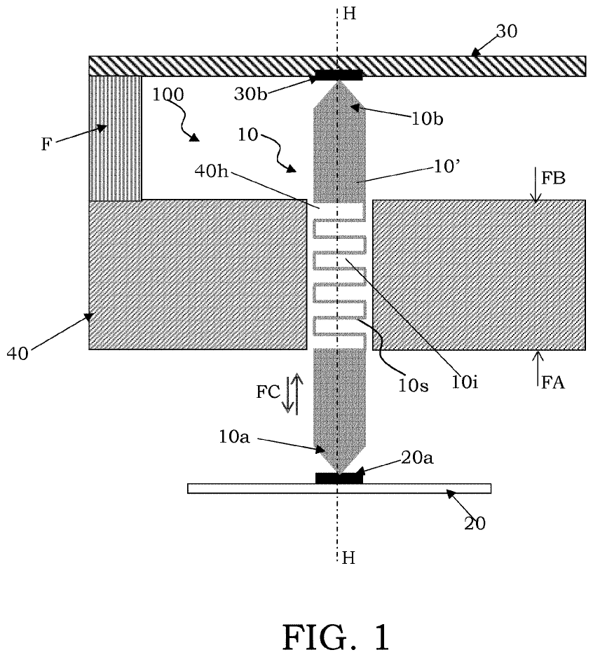

With the reference to the sectional view of FIG. 1, the probe head 100 first of all comprises a plurality of contact probes 10 intended to electrically contact the devices under test integrated in the semiconductor wafer 20 with the testing apparatus.

In order to house the contact probes 10, the probe head 100 comprises at least one guide 40 equipped with guide holes 40h inside which said contact probes 10 are housed. The guide 40 thus allows, together with the guide holes 40h thereof, to house, in particular to slidingly house, at least one portion of the contact probes 10.

Each contact probe 10 comprises a probe body 10′ extending along a longitudinal axis (indicated with reference H-H) between a first end 10a and a second end 10b, which ends are adapted to contact respective pads or contact pads. By way of example, the first end 10a (also called contact tip and indicated in the field with the term “plunger”) is adapted to contact pads 20a of the device under test integrated on the semiconductor wafer 20, whereas the second and opposite end 10b (also called contact head) is adapted to contact pads 30b of a space transformer or of a printed circuit board (PCB) which can be associated with the probe head 100, said component being generically identified with reference number 30 and being generically defined as “interface board”. In general, the term “end” thus means the terminal portions of the contact probe 10, said terminal portions comprising the contact points of the probe with the pads.

In an embodiment (as illustrated by simple way of example), the pads 30b are the pads of a PCB board, even if the use of an interposer arranged between the PCB and the contact heads of the probes is obviously not excluded.

Clearly, although the ends 10a and 10b in the attached figures end with a pointed shape, they are not limited thereto and can have any shape which is suited to the needs and/or circumstances.

Moreover, it is noted that, although the figures for simplicity show a single contact probe 10, the probe head 100 can comprise any number of contact probes, depending on the various applications.

In the embodiment of FIG. 1, a frame F acting as a structural support for the probe head 100 as a whole is also provided, in particular arranged between the guide 40 and the PCB 30, this frame F being omitted in the following figures only for simplicity of illustration.

Suitably, in order to enable high-frequency tests with high performances, the contact probe 10 has a reduced length, which is in particular lower than 2000 μm, preferably lower than 1000 μm, still more preferably equal to or lower than 800 μm, said length being measured along the longitudinal axis H-H of the probe. The self-inductance phenomenon is thereby suitably reduced and an effective testing even at very high frequencies, even in the radiofrequency domain, is ensured.

In order to ensure a proper contact with the pads 20a and 30b, in particular in order to ensure a proper control of the contact force, the contact probe 10 comprises at least one intermediate section 10s arranged between the first end 10a and the second end 10b which is elastically compliant (yielding) at least along the longitudinal axis H-H. The elastically compliant intermediate section 10s (also indicated below as “elastic section” of the probe) is configured to define the contact force FC (in particular the direction and/or intensity thereof) exerted by the contact probe 10 on the pads 20a and/or 30b, i.e. said contact force FC can be controlled due to the structure (shape/size) of said elastically compliant intermediate section 10s, and the probe acts as a spring.

In particular, in a preferred embodiment, the elastically compliant intermediate section 10s is suitably configured so that the contact probe 10 exerts a contact force FC, substantially directed along the longitudinal axis H-H, onto the contact pads 20a and 30b, even if in other embodiments there can be forces also with other components (for instance such as to also generate a scrub movement: in fact configurations in which the elastically compliant intermediate section is configured to generate a torsion on the pad, or a transversal scrub, are possible; in fact some embodiments can provide for elastically weaker portions and elastically stronger portions of the elastically compliant intermediate section 10s, as well as helical (not necessarily symmetrical) shapes for said elastically compliant intermediate section 10s.

In a non-limiting example of the present invention, the elastically compliant intermediate section 10s can be obtained by interdigitated engravings or notches 10i formed in the body 10′ of the contact probe 10, said interdigitated engravings or notches 10i being configured so that the contact probe 10 substantially acts as an elastic spring. The substantially spring-shaped elastically compliant intermediate section 10s can thus be formed for instance by removing some material, wherein the above notches 10i are made symmetrically with respect to the longitudinal axis H-H of the contact probe 10 (even if this is not strictly necessary and asymmetrical shapes with respect to said axis can be provided).

In general, the present invention is not limited by the particular method for manufacturing the contact probe 10, what matters is the presence of the above elastic section comprising a plurality of turns which follow each other along the longitudinal axis H-H, where the term “turn” indicates in the present description the single elastic element (or elastic sub-portion) of the spring which is repeated along said longitudinal axis H-H, thereby forming a given elastic pattern, as it will be detailed hereafter.

The intermediate section 10s is thus elastically compliant in a mainly longitudinal direction (but in other configurations other directions for the deformation of the elastic section and thus for the contact force FC can also be provided, as mentioned above), so as to get compressed along said direction during the testing of the device under test. In particular, the elastically compliant intermediate section 10s allows the contact probe 10 to shorten along the longitudinal direction thereof during the normal operation of the probe head 100, with a “spring effect” which ensures a proper contact force during the overdrive, and which also allows the contact probe 10 to come back to the original dimensions thereof once said probe head 100 has been spaced apart from the device under test.

It should be noted that, in the above-discussed embodiment, the contact probe 10 exerts the above contact force FC substantially directed along the longitudinal axis H-H onto the pads, whereas the component in the direction which is perpendicular to said longitudinal axis H-H is substantially null (or in any case reduced), thereby eliminating the risk of interlocking of the contact probe 10 in the guide hole 40h.

Preferably, the contact probe 10 has a non-circular cross section; in a preferred embodiment, the contact probe 10 has a rectangular section, for instance with one side having a length of 30 μm and the other side of the rectangle having a length of 70 μm, even if other dimensions can be obviously provided.

Furthermore, it is noted that the contact probe 10 can be made of a composite material, such as for instance layers of Pd, PdCo, Ni, NiCo, Au, Pt, Ag, Rh, and the like, without, however, being limited by the particular material used or by the manufacturing method. In general, selections of various materials or combinations of materials (such as for instance the above-described materials or combinations thereof) are possible depending on the needs and/or circumstances.

The elastically compliant intermediate section 10s extends along the longitudinal axis H-H of the contact probe 10 by a length of 1000 μm to 80 μm (preferably of about 200 μm), and with a pitch (i.e. a distance at rest between the centres of two adjacent turns) of 100 μm to 5 μm.

In the case in which an elastically compliant intermediate section 10s with a greater length is manufactured (still for the same overall length of the contact probe 10, which, as previously seen, is lower than 2000 μm, preferably equal to or lower than 800 μm), the stresses which the contact probe 10 is subjected to could be decreased.

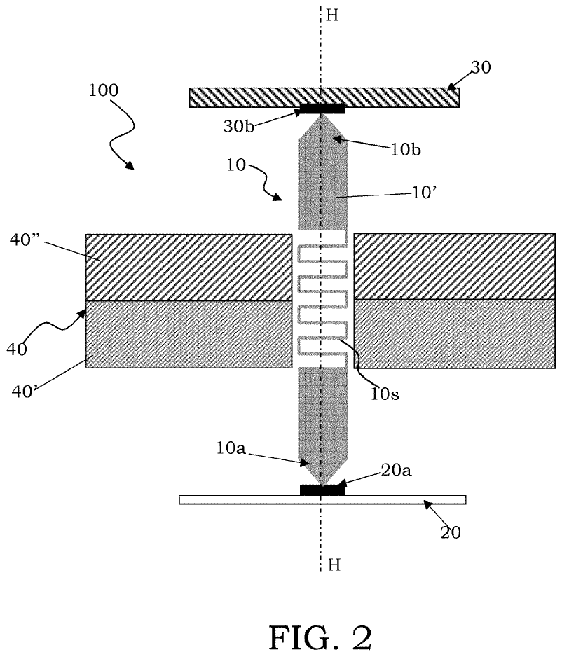

In order to accommodate the elastically compliant intermediate section 10s, a deep guide hole 40h is thus to be formed (for instance having a length which is higher than 300 μm). As illustrated in FIG. 2, in order to overcome this problem, instead of using a single guide 40 having a high thickness, two or more guides having a lower thickness associated with each other can be used. In other words, in an embodiment, the guide 40 may be structured in a first guide portion 40′ and in a second guide portion 40″. The second guide portion 40″ is initially made structurally independent of the first guide portion 40′ and is subsequently associated therewith, in particular it is fitted on the contact probe 10 after the latter has been introduced into the first guide portion 40′. For instance, the second guide portion 40″ can be overlapped to the first guide portion 40′, as well as it can be constrained thereto by attachment means, without limiting the present invention to particular attachment modes. Thereby, the guide holes of the single guide portions have smaller depths compared to the case in which a single guide is used, simplifying the formation of said holes.

A preferred embodiment has been described so far, in which a single guide 40 is provided (for instance having an overall thickness which is equal to 320 μm, even if other thicknesses are obviously possible, for instance higher thicknesses, thus allowing to extend the elastic section of the contact probe) and in which the elastically compliant intermediate section 10s is positioned at the guide 40 so as to be at least partially housed in the guide hole 40h, substantially in an intermediate position. In other words, an embodiment which envisages the presence of a single intermediate guide 40 which houses the elastic section of the contact probe 10 has been described so far. This embodiment is distinguished by a greater simplicity of assembly and lower production costs.

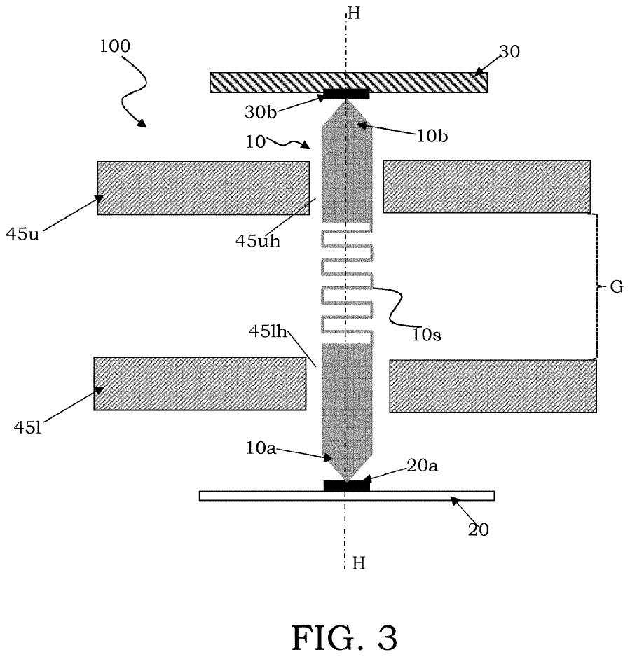

Alternatively, with reference to FIG. 3, the probe head 100 can comprise a lower guide 451 and an upper guide 45u separated from each other by an air gap or gap G, at which the elastically compliant intermediate section 10s lies, thus with the possibility of increasing the extension of this elastic section. The lower guide 451 and the upper guide 45u comprise respective lower guide holes 451h and upper guide holes 45uh for housing the contact probes 10.

In an embodiment (not illustrated in the figures), the lower guide holes 451h and the upper guide holes 45uh can possibly be shifted with respect to each other, i.e., with reference to a single probe, the centres thereof do not lie on a same longitudinal axis, thereby creating a slight deformation of the contact probe 10 to favour the retention and the possible contact thereof with the walls of the holes.

Moreover, it is known in the field that the fixed position of the power supply and ground signals (due for instance to the layout of the pads of the device under test) and the shape of the probes limit the control of the impedance of the signals inside the probe head, as well as they limit the control of the noise caused on the signal probes by other close signals, which limits the frequency performances of the probe head.

For this reason, in high-frequency applications (in particular RF applications), the ground probes (and also the power supply ones) are short-circuited through a metallization on the guide, thus short-circuiting probes of a same domain and making the ground contact available inside the probe head to also connect possible shields. Moreover, in the case of devices with different ground/power supply domains on the device then joined on the PCB, the metallization allows the loop inductance between a power supply and the related ground to be reduced.

For instance, consider the case in which a given power supply of a device under test is contacted by a single probe, which is short-circuited with other probes that carry power supplies sharing the same power supply unit. In such a case, when the current of this power supply meets the metallization which short-circuits all the probes of this domain, it splits among all the short-circuited probes, thereby allowing the inductance and equivalent resistance to be reduced compared to the case in which this current is confined in a single probe up to the PCB.

It is thus evident that the presence of metallizations on the guide, which short-circuit groups of probes and create a common conductive plane, allows the noise to be reduced and the frequency performances of the probe head to be increased.

Moreover, it is possible to short-circuit signal probes with each other as well, for instance based on the loop-back technique.

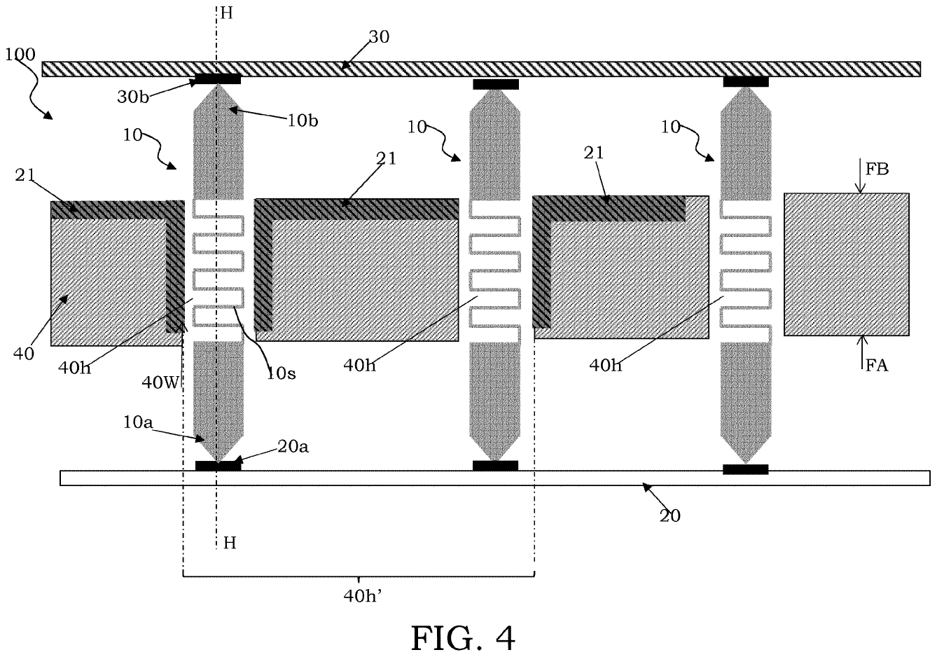

For this purpose, in accordance with embodiments of the present invention (as illustrated in FIG. 4), the guide 40 of the probe head 100 comprises at least one conductive portion 21 which includes and electrically connects the holes of at least one group (indicated with reference 40h′) of the guide holes 40h and which is adapted to contact, and thus to short-circuit, a corresponding group of contact probes, which are intended to carry a same type of signal, in particular intended to carry a given ground or power supply signal or operating signal.

Due to the conductive portion 21 formed on the guide 40, also indicated below as “metallization 21”, it is possible to form a given conductive domain, in which at least one portion of the contact probe 10 is in contact with said conductive portion 21.

In the non-limiting example of FIG. 4, two contact probes short-circuited by the conductive portion 21 and a contact probe electrically insulated therefrom are depicted, even if this is obviously only a schematic example and any number can be provided.

By way of example, the contact probes 10 short-circuited with each other by the conductive portion 21 can be contact probes intended to carry ground signals, as well as they can be contact probes intended to carry the power supplies. In other words, in the probe head 100, the contact probes short-circuited with each other due to the metallization of the guide 40 and housed in the group 40h′ of the guide holes 40h are adapted to carry a same ground or power supply signal, with resulting increase in the performances of the probe head.

Furthermore, as mentioned above, the short-circuited probes can also be contact probes intended to carry the input/output operating signals between the device under test and the testing apparatus interfaced with the probe head 100, as it occurs for instance in the loop-back technique.

In any case, the conductive portion 21 is such as to form a common conductive plane in the probe head, which is very useful, especially in the high-frequency testing that the short contact probes 10 are able to perform.

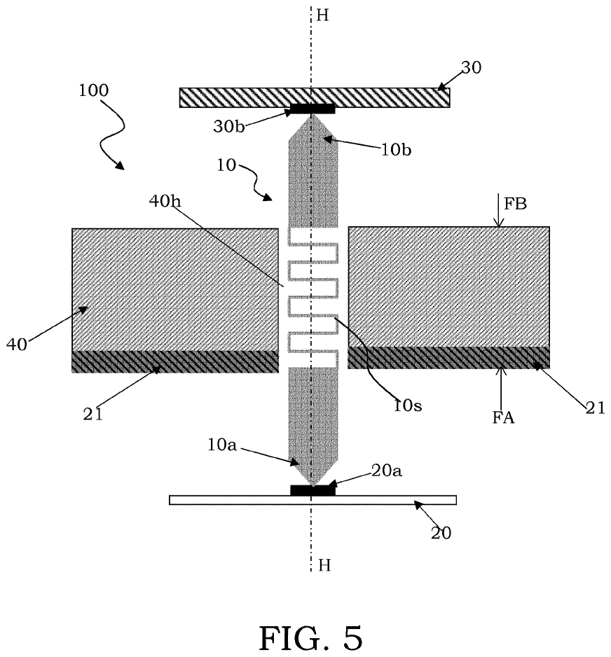

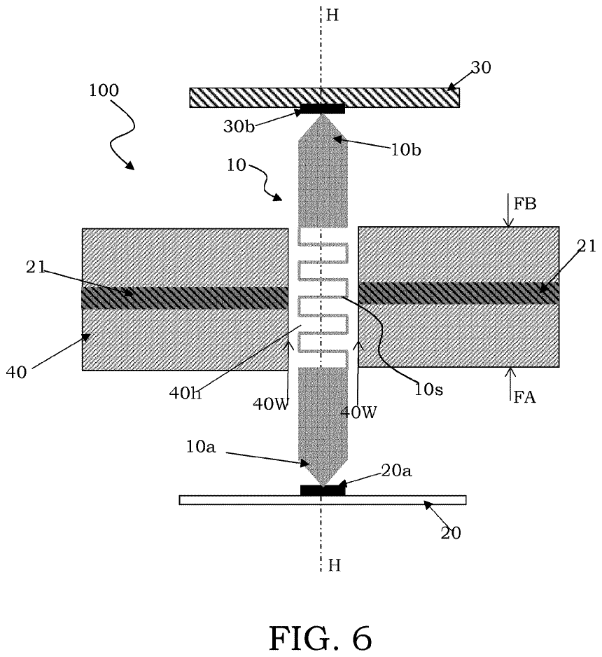

Obviously, the probe head 100 can comprise any number of conductive portions 21 arranged in any way on the guide or even embedded therein, to carry any type of signal. For instance, the conductive portion can be formed on an upper face FB of the guide 40 (as illustrated in FIG. 4), or it can be arranged on a lower face FA thereof (as illustrated in FIG. 5), as well as it can be formed inside said guide 40 (i.e. embedded in the guide 40, as represented in FIG. 6).

Moreover, it is possible to provide for the presence of a first conductive portion which short-circuits ground probes and a second conductive portion which short-circuits power supply probes arranged on an opposite face of the guide, as well as many other configurations can be provided for, as described for instance in the international patent application number PCT/EP2017/082180 in the name of the Applicant.

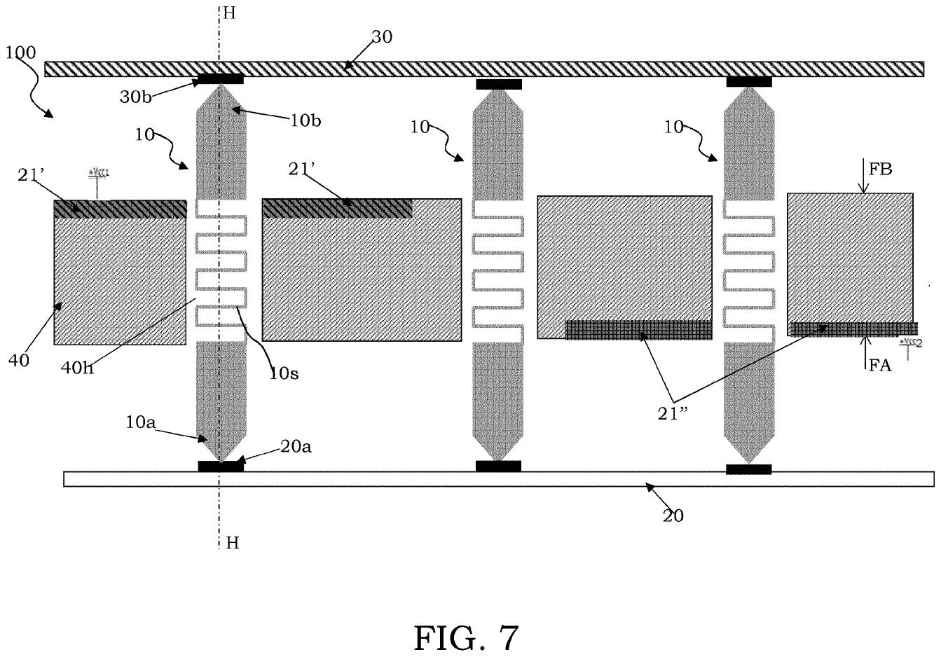

By mere way of example, as illustrated in FIG. 7, it is possible to provide for a plurality of conductive portions 21′ and 21″ corresponding to a plurality of different conductive domains (for instance different power domains), these conductive portions 21′ and 21″ being arranged on opposite faces of the guide 40 (as illustrated in the non-limiting example of FIG. 7) and/or embedded in said guide 40, or even on the same face of the guide 40.

The manufacturing method of the conductive portion is also not limited to a particular one, for instance it can be formed by depositing conductive material on the ceramic guide.

In other words, the present invention is not limited by the number and arrangement of the conductive portions, which can be set based on the needs and/or circumstances.

In any case, what matters is that the presence of the at least one conductive portion 21 allows a common conductive plane to be formed, which electrically connects several contact probes to each other (i.e. the contact probes 10 housed in the group of holes 40h′), which, as previously seen, are equipped with the elastically compliant intermediate section 10s and have a reduced length, thus increasing the performances of the probe head 100 as a whole.

Furthermore, the conductive portion 21 may coat at least one portion of the walls 40W of the guide holes of the group 40h′, thereby forming a metallized portion of the guide hole with which the contact probe 10 is in contact, in particular with which the contact probe 10 makes a sliding contact.

Preferably, the conductive portion 21 can entirely cover some or all of the walls of the guide holes (and thus in this case the metallized portion coincides with the entire wall 40W of the holes), or it is possible to provide for a configuration in which this conductive portion 21 only partially covers the wall 40W of the guide holes.

Further, in an embodiment that is not shown, only a metal layer at least partially covering the walls of the hole may be present, and the elastically compliant intermediate section is in contact with said layer.

Given the importance of the conductive portion 21, there is thus the need to ensure an optimum contact between the contact probes 10 and said conductive portion 21 (for instance between the probes and the metallized walls of the guide holes) during the testing of the device, for instance there is the need to always ensure the above sliding contact between probe and hole (even if in some configurations this contact can be a pressing contact, for instance an abutment of a stopper on a conductive portion, as it will be discussed below).

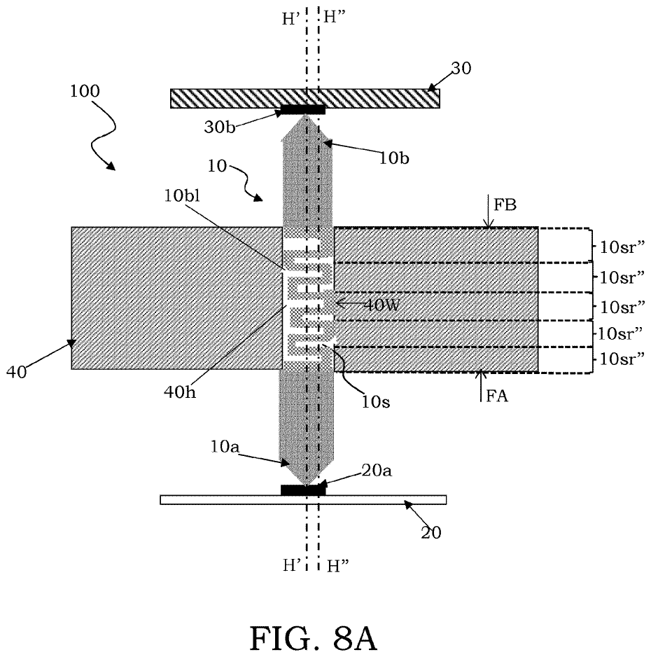

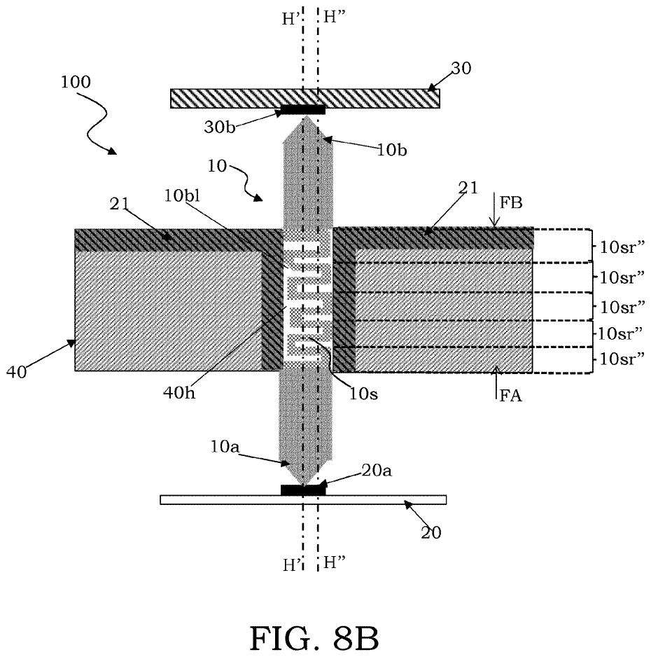

Advantageously according to the present invention, as illustrated in FIGS. 8A and 8B, the elastically compliant intermediate section 10s is split into a plurality of elastic sub-portions or elastic elements or elastic half-sections (indicated with reference 10sr″) which are not aligned with each other with respect to a same reference axis (for instance they are shifted from each other with respect to the longitudinal axis H-H of the probe when taken as a reference).

For instance, the elastic elements 10sr″ develop along respective axes, possibly parallel to each other (indicated with references H′-H′, H″-H″), not necessarily coinciding with the longitudinal axis H-H of the probe.

In other words, the elastically compliant intermediate section 10s is formed by various sections (i.e. the elastic elements) which are not aligned along the longitudinal axis of the contact probe 10, i.e. along a vertical reference axis.

The elastic elements 10sr″ follow each other in series without interruption and are shifted (i.e. offset along the vertical reference axis) from each other, so as to define an elastically compliant intermediate section which is not rectilinear as a whole, being the respective axes of symmetry non-coincident with each other (suitably shifted).

Suitably, at least one of said elastic elements 10sr″ is in contact with a wall 40W of the guide hole 40h, in particular with the conductive portion 21 which extends in said hole (as illustrated in FIG. 8B), thus establishing the desired electric contact with the metallization, while ensuring a proper and simple retainment of the contact probe 10.

In general, in short, in accordance with the present invention, the elastically compliant intermediate section 10s is thus structured as a plurality of elastic elements 10sr″ which follow each other in series so that said elastically compliant intermediate section is non-rectilinear in section, wherein at least one of said elastic elements is in contact with a wall of the guide hole. In particular, at least two of the elastic elements 10sr″ can be shifted from each other with respect to a reference axis which is orthogonal to the guide, i.e. a vertical axis (for instance the longitudinal axis H-H of the contact probe 10, as previously seen).

Suitably, the elastic elements 10sr″ of the elastically compliant intermediate section 10s follow each other so that said elastically compliant intermediate section 10s is non-rectilinear even at rest conditions (i.e., not only when compressed), and the contact with the wall of the guide hole occurs at least through at least one of said elastic elements 10sr″ (i.e., through at least a portion of the elastically compliant intermediate section 10sr″ due to the shape thereof).

In an embodiment, the elastically compliant intermediate section 10s is shaped differently from the rest of the contact probe and therefore corresponds to a different portion of the contact probe (e.g., different with respect to the end portions).

In accordance with an embodiment, one or more of the edges of the elastic elements 10sr″ (in particular the edges of the elastic elements in contact with the walls 40W of the guide hole 40h, i.e. the projecting portions loops) is bevelled (i.e. it comprises a bevelling 10bl), in order to avoid interlockings of the contact probe 10 in the guide hole, in particular interlockings during the assembly.

This geometry is advantageous since it ensures that, during the testing of the device under test, the contact probe 10 stays in place, while keeping a proper contact with the walls of the guide hole 40h and thus with the related metallization. In particular, according to the present invention, the elastic section 10s has (at least locally) sectional dimensions which are greater than the ones of the guide hole 40h (as illustrated in FIGS. 8A and 8B), generating a friction between said elastic section 10s and the walls of said guide hole 40h. This friction prevents the contact probes 10 from exiting the guide 40, for instance during the maintenance of the probe head 100, and ensures a better electrical contact with the conductive portion 21 (FIG. 8B).

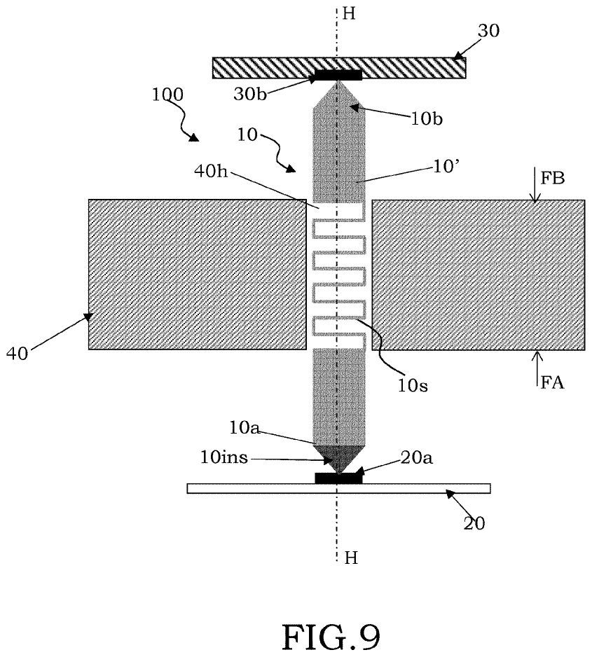

Referring now to the embodiment of FIG. 9, the first end 10a of the contact probe 10 (i.e. the lower end) can comprise a high-hardness material 10ins, in particular with a higher hardness compared to the material of the probe body 10′, such as rhodium for instance.

Obviously, FIG. 9, in which the high-hardness material makes the entire terminal section of the contact probe 10, is provided only by way of example and other configurations can be provided, where in general the high-hardness material 10ins can be adapted to perform the contact with the pads 20a of the device under test and it is thus such as to ensure a contact tip at least partially having a high hardness. For instance, in an embodiment, the high-hardness material 10ins can be an insert supported by a complementary section of the probe body 10′ and intended to contact the pads 20a of the device under test, or it can be a coating of the first lower end 10a.

This embodiment of FIG. 9 ensures a high service life of the contact probe 10, while keeping a high-quality contact.

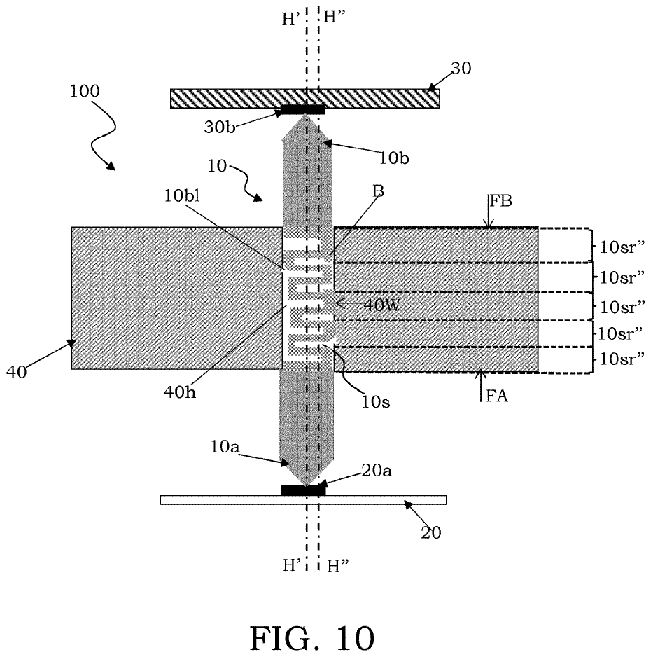

Furthermore, referring now to FIG. 10, it is noted that the presence of the elastically compliant intermediate section 10s, characterized by several loops (and more generally by the succession of various elastic elements 10sr″ or portions or elastic sub-sections forming this elastic section, as described in the previous examples), increases the actual length of the contact probe 10; in order to solve this problem, the elastically compliant intermediate section 10s comprises, at at least one of the elastic elements thereof, at least one projecting element or bump (reference B) configured to contact, during the testing of the device under test (i.e. when the elastic section compresses), an adjacent elastic element, causing an electrical connection between said elastic elements which reduces the actual length of said elastically compliant intermediate section 10s and improves the performances of the probe head 100.

As a result, in this embodiment, at least one of the elastic elements of the elastically compliant intermediate section 10s comprises a projecting element B protruding toward an adjacent elastic element and configured to contact a portion of said adjacent elastic element during the testing of the electronic device, said portion being separated from said projecting element B under the rest conditions (i.e. when the elastic section is not compressed).

In other words, in this embodiment, the elastically compliant intermediate section 10s comprises the projecting element B configured to cause the electrical contact between portions of said elastically compliant intermediate section 10s which otherwise would be separated.

The projecting element B can be formed integral with the elastically compliant intermediate section 10s, without the present invention being limited by a manufacturing method.

For instance, the projecting element B can be formed at an edge or loop of the respective elastic element, even if other configurations are possible.

It is also possible to provide a plurality of projecting elements B, whose number is selected based on the selected length in compression of the elastically compliant intermediate section 10s, i.e. based on the length to be obtained; the more projecting elements B are present, the greater is the length of the elastic section in compression, for which reason it is preferable to keep a limited number of said projecting elements B.

Finally, further stopping means may also be provided, such as stoppers abutting onto the guide or clips interfering with the holes (for example at the top and/or the bottom), not illustrated in the attached figures, in combination with the discussed above geometry.

Summarizing the above, in conclusion, the present invention thus allows successfully overcoming the technical problem, providing the above probe head (which comprises very short contact probes acting as elastic springs) and solving all the drawbacks of the prior art in a simple way.

It is possible to effectively control the intensity of the contact force and more generally the compression of the contact probes, suitably shaping and sizing the elastically compliant intermediate section.

In general, whatever the manufacturing method is (for instance removal of some material from the body locally reducing the rigidity thereof), a reduced-rigidity elastic section is obtained, said elastic section being formed by elastic elements which follow each other and represent the fundamental units thereof.

The reduced length of the contact probes, which can thus be seen as micro-springs, makes the probe head of the present invention suited to test high-frequency devices, while solving the problem of the rigidity of the short probes of the known solutions.

Advantageously according to the present invention, the above described configuration allows ensuring a proper stability of the contact probes, as well as they allow the proper retention thereof and a simple assembly.

Unlike the vertical probe heads manufactured according to the prior art, the probe head according to some embodiments further allows using a single guide, the contact probes deforming inside the guide hole. The use of a single guide simplifies the operations of assembling the probe head.

Moreover, the probe head according to the invention has a limited consumption of the contact pads due to the advantageous shape thereof.

Finally, it is noted that all of the above embodiments can be combined with each other, even when the combination is not expressly illustrated or described; for instance, the particular non-rectilinear shape of the elastically compliant intermediate section according to the present invention may be combined with a particular arrangement of the metallizations, or with various configurations of the guides, or even with the presence of stop means, as well as with other configurations. Indeed, most figures report, for the sake of simplicity, a contact probe with an elastically compliant intermediate section having a stepped section, but the various illustrated embodiments for said stepped section are also applicable to the geometry according to the invention.

Obviously, in order to meet contingent and specific requirements, a person skilled in the art can bring to the above-described probe head several modifications and variants, all falling within the scope of protection of the invention as defined by the following claims.

1. A probe head for testing electronic devices, comprising:
at least one contact probe comprising a body which extends between a first end and a second end, said ends being adapted to contact respective contact pads; and
at least one guide comprising at least one guide hole configured to house at least one portion of the contact probe,
wherein the contact probe comprises at least one intermediate section arranged between the first end and the second end said intermediate section being elastically compliant, and
wherein the elastically compliant intermediate section is structured as a plurality of elastic elements which follow one another in series in such a way that said elastically compliant intermediate section is not rectilinear, wherein at least one of said elastic elements is in contact with a wall of the guide hole.

2. The probe head according to claim 1, wherein at least two of said elastic elements are offset to each other with respect to a reference axis that is orthogonal to the guide.

3. The probe head according to claim 1, wherein the elastic elements extend along respective axes, which are shifted with respect to each other such that said elastic elements are offset to each other.

4. The probe head according to claim 1, wherein one or more of the edges of the elastic elements in contact with the walls of the guide hole are beveled.

5. The probe head according to claim 1, further comprising a conductive portion formed on the guide, said conductive portion including at least one group of said guide holes and being adapted to contact and short-circuit a corresponding group of contact probes that are housed in said group of holes and are intended to carry a given type of signal, thereby forming a conductive domain, wherein at least one portion of the contact probe is in contact with said conductive portion.

6. The probe head according to claim 5, wherein at least one portion of at least one wall of the guide hole is covered by the conductive portion, and wherein the contact between the contact probe and the conductive portion also occurs through said metalized wall.

7. The probe head according to claim 5, wherein at least one of the elastic elements is configured to contact the conductive portion.

8. The probe head according to claim 1, wherein the contact probr has a length lower than 2000 μm, preferably lower than 1000 μm, even more preferably equal to or lower than 800 μm, said length being measured along a longitudinal axis of the contact probe.

9. The probe head according to claim 1, wherein the elastically compliant intermediate section is positioned at the guide, so as to be at least partially housed in the guide hole.

10. The probe head according to claim 1, wherein the first end of the contact probe comprises a material with high hardness, such as rhodium.

11. The probe head according to claim 1, wherein at least one of said elastic elements comprises a projecting element which protrudes towards an adjacent elastic element and is configured to contact a portion of said adjacent elastic element during the testing of the electronical device, said portion being separated from said projecting element in rest conditions.
